(19) United States
(12) Patent Application Publication
(10) Pub. No.: US 2013/0130503 A1
(43) Pub. Date: May 23, 2013

(54) METHOD FOR FABRICATING ULTRA-FINE NANOWIRE

(71) Applicants: Ru Huang, Beijing (CN); Shuai Sun, Beijing (CN); Yujie Ai, Beijing (CN); Jiewen Fan, Beijing (CN); Runsheng Wang, Beijing (CN); Xiaoyan Xu, Beijing (CN)

(72) Inventors: Ru Huang, Beijing (CN); Shuai Sun, Beijing (CN); Yujie Ai, Beijing (CN); Jiewen Fan, Beijing (CN); Runsheng Wang, Beijing (CN); Xiaoyan Xu, Beijing (CN)

(73) Assignee: Peking University

(21) Appl. No.: 13/511,624

(22) PCT Filed: Feb. 3, 2012
(86) PCT No.: PCT/CN12/70858

§ 371 Date: May 23, 2012

(30) Foreign Application Priority Data
Nov. 23, 2011 (CN) 201110375066.5

(51) Int. Cl. H01L 21/308; B82Y 40/00

(52) U.S. Cl. 438/703; 977/901; 257/E21.231

(57) ABSTRACT

Disclosed herein is a method for fabricating an ultra-fine nanowire by combining a trimming process and a mask blocking oxidation process. The ultra-thin nanowire is fabricated by a combination of performing a trimming process on a mask to reduce a width of the mask and blocking an oxidation through the mask. A diameter of the floated ultra-thin nanowire fabricated by the method is controlled to 20 nm below by a thickness of a deposited silicon oxide film, a width of the silicon oxide nanowire after trimming, and a time and a temperature for performing a wet oxidation process. Also, since a speed of the wet oxidation process is faster, the width of the nanowire obtained by a conventional photolithography is reduced faster. Moreover, when fabricating an ultra-thin nanowire by using the method, the cost is reduced and it is more feasible to be implemented.

### CROSS-REFERENCES TO RELATED APPLICATION

The present application claims priority to Chinese Patent Application No. 201110375066.5, filed on Nov. 23, 2011, which is incorporated herein by reference in its entirety.

### FIELD OF THE INVENTION

An embodiment of the prevent invention relates to a field of manufacturing a transistor in a microelectronic semiconductor device, and more particularly, relates to a method for fabricating an ultra-fine nanowire by combining a trimming process and a mask blocking oxidation process.

### BACKGROUND OF THE INVENTION

With the development of integrated circuit industry, a higher integration degree is demanded more and more, and a feature size of a field effect transistor is required to be scaled down accordingly. At the same time, it is desirable to obtain a better performance and a lower manufacturing cost. In manufacturing, there has been a stricter requirement for a photolithography process. Electron beam lithography is widely used at present owing to its precise control on a width of a pattern in fabricating a nano wire. However, some drawbacks, such as a low efficiency and a high cost, are existed as well, thus limiting the application of the electron beam lithography in a mass manufacturing. Further, during the electron beam lithography, an electron scattering may occur, which leads to a proximity effect and causes a huge challenge when fabricating a nanowire smaller than 20 nm.

### SUMMARY OF THE INVENTION

An object of an embodiment of the present invention is to provide a method for fabricating an ultra-finenanowire by combining a trimming process and a mask blocking oxidation process.

The above-mentioned object of the present invention is achieved by a technical solution as follows.

A method for fabricating an ultra-fine nanowire includes the following steps.
(1) Fabricating an Oxidation Blocking Layer on a Substrate

A main object of the step is to fabricate an oxidation blocking layer for a surface of a silicon nanowire during a subsequent oxidation process. A silicon oxide film and a silicon nitride film are used as the oxidation blocking layer. A thickness to which the surface of the silicon nanowire is oxidized in the oxidation process is determined by a thickness of the oxidation blocking layer. The step particularly includes:

a. depositing a silicon oxide film on silicon substrate;

b. depositing a silicon nitride film;

c. coating a photoresist on the silicon nitride film, and defining a region where a hard mask for the siliconnanowire is to be formed through a photolithography process;

d. transferring a pattern of the photoresist onto the silicon oxide film and the silicon nitride film though a dry etching process.
(2) Performing a Dry Etching Process on the Substrate to Form a Primarynanowire, Removing the Photoresist, and Performing a Trimming Process on a Silicon Oxide Mask to Form a Width-Reduced Nanowire

A main object of the step is to perform a trimming process on the silicon oxide mask by wet etching, so as to reduce a width of the silicon oxide mask. The width of the silicon oxide mask will be determined by a ratio and a concentration of the wet etching solution used in the trimming process as well as a time for performing the trimming process, which will in turn have a direct influence on a width of a final nanowire.
(3) Performing a Wet oxidation on the Nanowire and Removing the Mask on top of the Nanowire by a WEet Etching Process so as to Form a Suspended Silicon Nanowire

By performing a wet oxidation process on the silicon nanowire, a silicon nanowire of a very small width is obtained. In the step, for a top portion of the silicon nanowire on which the silicon oxide mask is covered, oxidation thereof is blocked by the silicon oxide mask, while side surfaces and other top portions of the silicon nanowire where are not protected by the silicon oxide mask are oxidized. A thickness of the oxidation layer over the side surfaces and other top portions of the silicon nanowire where are not protected by the silicon oxide mask is much larger than a thickness of the oxidation layer over the top portion of the silicon nanowire protected by the silicon oxide mask . A width of the silicon nanowire is determined by an oxidation time and an oxidation temperature used in the step. Further, a width of the final silicon nanowire is determined by the oxidation time and the oxidation temperature in the step.

The step includes:.

a. performing a wet oxidation process on the nanowire formed in the step (2);

b. removing the silicon nitride mask surrounding on top of the nanowire through a wet etching process; and

c. removing an oxidation layer surrounding the nanowire through a wet etching process;

In the above method, a low pressure chemical vapor deposition process is used in the depositing of the silicon oxide film and the silicon nitride film. A conventional photolithography is used in the definition of the photoresist. An anisotropic dry etching process is used in the etching of the silicon oxide film, the silicon nitride film and the substrate. A BHF solution (HF:NH4F=1:40 (volume ratio)) is used in the trimming of the silicon oxide mask. A wet oxidation process is used in the oxidation of the nanowire. A hot concentrated phosphoric acid is used in the wet etching process of the silicon nitride mask, and a hydrogen fluoride solution is used in the wet etching process of the oxidation layer.

A technical advantage and effect of the embodiment of invention is as follows.

In a fabricating process of integrated circuit, since an integrated degree is getting higher and higher, a width of a nanowire pattern is required to be smaller and smaller, and meanwhile an industry cost is desirable to be reduced. If the fine nanowire is fabricated by using an electron beam lithography and an etching process, the cost is substantially high, which is not advantageous in a industry manufacturing. Further, if the nanowire is oxidized though an oxidation approach in order to reduce the width of the nanowire, it is certain to extend a reaction time, thus limiting the manufacturing and application for industry production. In the present invention, a process method for fabricating an ultra-thin nanowire by a combination of performing a trimming process on a mask to reduce a width of the mask and blocking an oxidation through the mask is provided. By initially performing a trimming process on the mask, the width of the mask is reduced, and meanwhile only an top portion of a primary nanowire is blocked from being oxidized. Moreover, by further performing a wet oxidation process, sides and a part of the top portion of the nanowire are oxidized at the same time, while other part of the top portion is blocked from being oxidized by the mask, and thus the width of the nanowire is considerably reduced. A diameter of the floated ultra-thin nanowire fabricated by the method can be controlled to 20 nm below by a thickness of a deposited silicon oxide film, a width of the silicon oxide nanowire after trimming, and a time and a temperature for performing a wet oxidation process. Also, since a speed of the wet oxidation process is faster, the width of the nanowire obtained by a conventional photolithography is reduced faster. Moreover, when fabricating an ultra-thin nanowire by using the method, the cost is reduced and it is more feasible to be implemented.

### BRIEF DESCRIPTION OF THE DRAWINGS

FIG. 1(a)-(l) are views schematically showing a process flow for fabricating an ultra-fine nanowire based on a combination of a trimming process and a mask blocking oxidation process according to an embodiment of the invention.

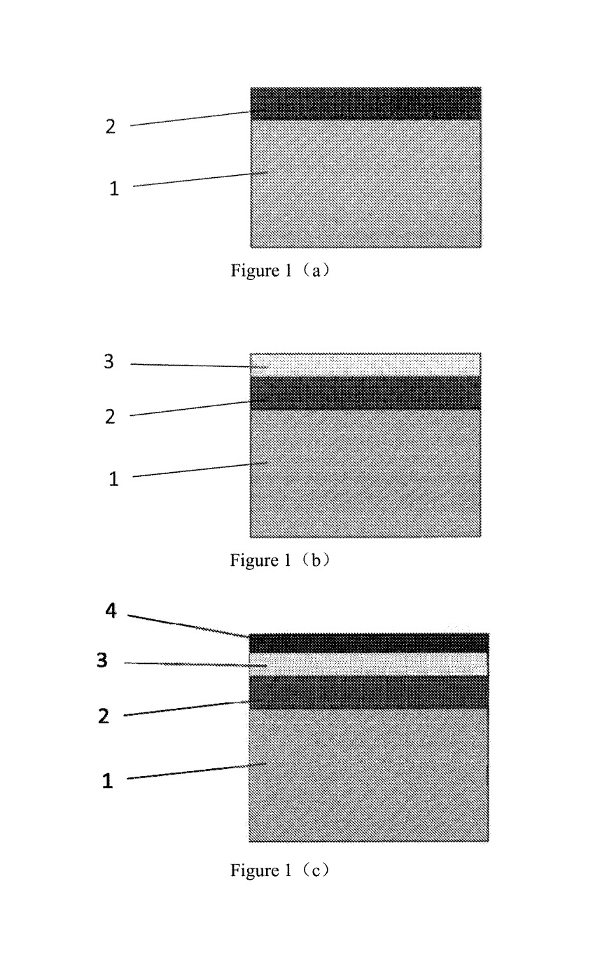

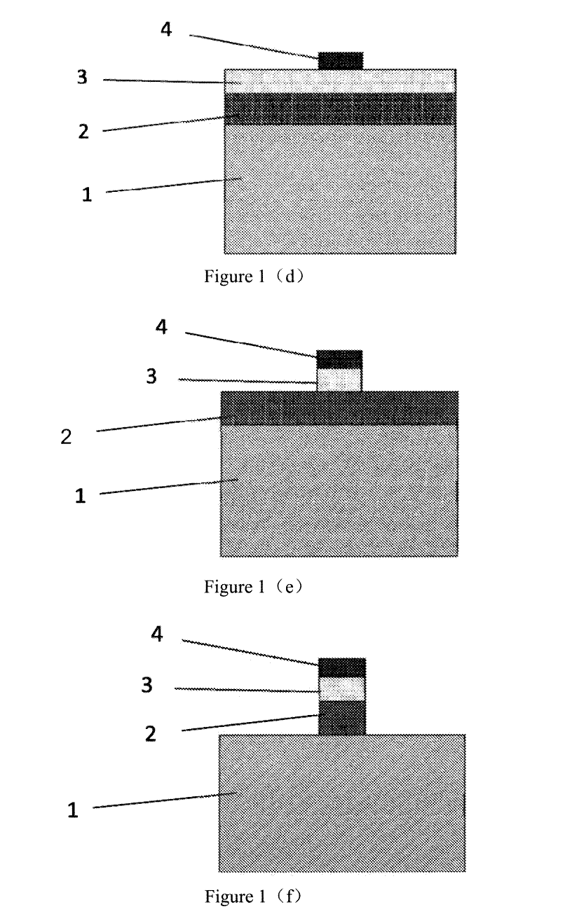

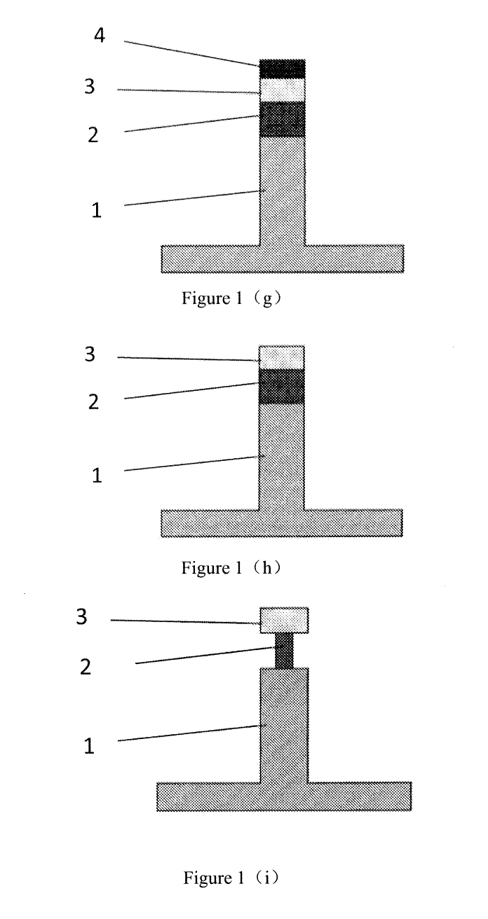

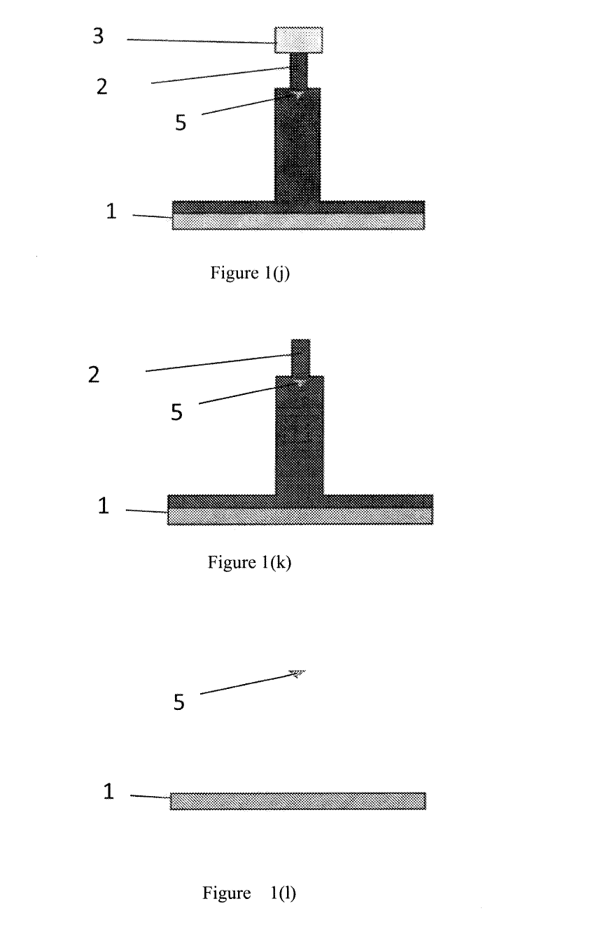

In figures, FIG. 1(a) illustrates a step of depositing a silicon oxide film on a substrate; FIG. 1(b) illustrates a step of depositing a silicon nitride film; FIG. 1(c) illustrates a step of coating a photoresist; FIG. 1(d) illustrates a step of performing a photolithography process; FIG. 1(e) illustrates a step of performing a dry etch process on the silicon nitride film to remain a silicon nitride film pattern on the substrate; FIG. 1(f) illustrates a step of performing a dry etching process on the silicon oxide film; FIG. 1(g) illustrates a step of performing a dry etching process on the substrate; FIG. 1(h) illustrates a step of removing the photoresist; FIG. 1(i) illustrates step of performing a trimming process on the silicon oxide film by using a BHF solution; FIG. 1(j) illustrates a step of performing a wet oxidation process; FIG. 1(k) illustrates a step of removing the silicon nitride mask on top layer; and FIG. 1(l) illustrates a step of removing an oxide layer surrounding the nanowire to obtain a fine nanowire.

In the figures, reference sign “1” denotes a substrate; reference sign “2” denotes a silicon oxide film; reference sign “3” denotes a silicon nitride film; reference sign “4” denotes a photoresist; and reference sign “5” denotes a fine nanowire of the substrate material.

### DETAILED DESCRIPTION OF THE EMBODIMENTS

A detailed description of the invention will be described with reference to the accompany drawings and an embodiment.

An ultra-fine nanowire with a diameter of about 20 nm may be fabricated by the following steps.

1. A silicon oxide film with a thickness of 1500 Å is deposited on a silicon substrate through a low pressure chemical vapor deposition process, as shown in FIG. 1(a).

2. A silicon nitride film with a thickness of 500 Å is deposited through a low pressure chemical vapor deposition process, as shown in FIG. 1(b).

3. A photoresist is coated on the silicon nitride film, as shown in FIG. 1(c).

4. A region where a hard mask for the silicon nanowire is to be formed is defined through a photolithography process, as shown in FIG. 1(d).

5. The silicon nitride film is etched by 500 Å through an anisotropic dry etching process, so as to transfer a pattern of the photoresist onto the silicon nitride film, as shown in FIG. 1(e).

6. The silicon oxide film is etched by 1500 Å through an anisotropic dry etching process, an as to transfer the pattern of the photoresist onto the silicon oxide film, as shown in FIG. 1(f).

7. The silicon substrate is etched by 3000 Å through an anisotropic dry etching process, as shown in FIG. 1(g).

8. The photoresist is removed, as shown in FIG. 1(h).

9. A trimming process is performed on a silicon oxide nanowire to form a nanowire by using a BHF solution (HF:NH4F=1:40 (volume ratio)), with a speed of about 6 Å/s, as shown in FIG. 1(i).

10. A wet-oxygen oxidation process is performed on the nanowire at 950° C. for 4 h, so that a width of the silicon nanowire is slimmed by the oxidation process, as shown in FIG. 1(j).

11. The silicon nitride is etched by 500 Å through a hot (170° C.) concentrated phosphoric acid, as shown in FIG. 1(k);

12. A wet etching process is performed on the silicon oxide by using a solution of hydrofluoric acid in which the volume ratio of hydrofluoric acid to water is 1:10 until the entire substrate is dehydrated.

Thereby, a nanowire with a relatively small width is finally obtained.

The specific embodiments of the present invention are not used to limit the invention. Various changes, modifications or equivalents of the embodiments to the technical solution of the present invention can be made by those skilled in the art by using the above-mentioned methods and techniques without departing from the spirit or scope of the invention. Thus, it is intended that the present invention covers all such modifications changes, modifications or equivalents of the embodiments without departing from the spirit or scope of the invention they come within the scope of the appended claims.

What is claimed is:

1. A method for fabricating an ultra-fine nanowire, comprising:
1) fabricating an oxidation blocking layer over a substrate;
2) performing a dry etching process on the substrate to form a primary nanowire, removing a photoresist, and performing a trimming process on a silicon oxide mask nanowire to form a width-reduced nanowire; and
3) performing a wet oxidation on the nanowire, and removing a mask on top of the nanowire by a wet etching process, so as to form a floated silicon nanowire.

2. The method according to claim 1, wherein, the step 1) comprises:
a. depositing a silicon oxide film over the substrate;
b. depositing a silicon nitride film;
c. coating a photoresist on the silicon nitride film, and defining a region where a hard mask for the silicon nanowire is to be formed through a photolithography process; and
d. transferring a pattern of the photoresist onto the silicon nitride film and the silicon oxide film though a dry etching process.

3. The method according to claim 2, wherein, the step 3) comprises:
a. performing a wet oxidation process on the nanowire formed in the step (2);
b. removing the silicon nitride mask surrounding the top of the nanowire through a wet etching process; and
c. removing an oxidation layer surrounding the nanowire through a wet etching process;

4. The method according to claim 3, wherein, a low pressure chemical vapor deposition process is used in the depositing of the silicon oxide film and the silicon nitride film, a conventional photolithography is used in the definition of the photoresist, and an anisotropic dry etching process is used in the etching of the silicon oxide film, the silicon nitride film and the substrate.

5. The method according to claim 3, wherein, a BHF solution is used in the trimming of the silicon oxide mask.

6. The method according to claim 3, wherein, a hot concentrated phosphoric acid is used in the wet etching process of the silicon nitride mask, and a hydrogen fluoride solution is used in the wet etching process of the oxidation layer.
